(19) United States
(12) Patent Application Publication
(10) Pub. No.: US 2016/0163613 A1
(43) Pub. Date: Jun. 9, 2016

(54) ELECTRONIC APPARATUS

(71) Applicant: DENSO CORPORATION, Aichi (JP)

(72) Inventors: Shinya UCHIBORI, Kariya-city (JP); Norihisa IMAIZUMI, Kariya-city (JP); Masayuki TAKENAKA, Kariya-city (JP)

(21) Appl. No.: 14/900,651

(22) PCT Filed: Jun. 24, 2014
(86) PCT No.: PCT/JP2014/003376

§ 371 Date: Dec. 22, 2015

(30) Foreign Application Priority Data
Jun. 28, 2013 (JP) 2013-136900
May 21, 2014 (JP) 2014-105060

(51) Int. Cl. H01L 23/31; H05K 1/18; H01L 23/498

(52) U.S. Cl. CPC H01L 23/3157; H01L 23/49827; H01L 23/49811; H05K 1/181

(57) ABSTRACT

An electronic apparatus includes a board, a first electronic component, a mold resin and a second electronic component. The board has a first surface and a second surface opposite to the first surface. The first electronic component is mounted on the first surface of the board. The mold resin seals the first electronic component and the first surface of the board. The second electronic component is arranged on the mold resin.

### CROSS REFERENCE TO RELATED APPLICATION

This application is based on Japanese Patent Application No. 2013-136900 filed on Jun. 28, 2013 and Japanese Patent Application No. 2014-105060 filed on May 21, 2014, the disclosure of which are incorporated herein by reference.

### TECHNICAL FIELD

The present disclosure relates to an electronic apparatus including a first electronic component mounted on a board and encapsulated in a mold resin, and a second electronic component mounted on the mold resin.

### BACKGROUND ART

An electronic apparatus has hitherto been proposed in, for example, Patent Literature 1, which includes a board having a first surface and a second surface, an electronic component mounted on the first surface of the board, and a mold resin for encapsulating the first surface of the board and the electronic component.

### PRIOR ART LITERATURES

### Patent Literature

Patent Literature 1: JP 2010-141158-A

### SUMMARY OF INVENTION

Such an electronic apparatus including the electronic component encapsulated in the mold resin may be turned into an electronic apparatus including even more electronic components mounted thereon. In this case, simply, additional electronic components are disposed on a portion, which is not encapsulated in the mold resin, of the first surface of the board. With such a structure, however, the board becomes larger in size by the number of additional electronic components to be mounted.

Examples of the electronic components to be additionally disposed outside the mold resin include electronic components that are likely to be broken by the pressure applied during the molding of the mold resin.

An object of the present disclosure is to provide an electronic apparatus including an electronic component encapsulated in a mold resin and an electronic component disposed outside the mold resin, the electronic apparatus enabling a reduction in size of a board.

### OBJECTS TO SOLVE DIFFICULTY

An electronic apparatus according to an aspect of the present disclosure includes: a board having a first surface and a second surface opposite to the first surface; a first electronic component mounted on the first surface of the board; a mold resin encapsulating the first electronic component and the first surface of the board; and a second electronic component disposed on the mold resin.

With this configuration, as compared to an electronic apparatus including a second electronic component disposed on a portion, which is not encapsulated in a mold resin, of a first surface of a board, the board can be made smaller.

### BRIEF DESCRIPTION OF DRAWINGS

The above and other objects, features and advantages of the present disclosure will become more apparent from the following detailed description made with reference to the accompanying drawings. In the drawings:

FIG. 1 is a plan view of an electronic apparatus according to a first embodiment of the present disclosure;

FIG. 2 is a cross-sectional view taken along line II-II in FIG. 1;

FIG. 3 is a cross-sectional view taken along line in FIG. 1;

FIG. 4 is a cross-sectional view of an electronic apparatus according to a second embodiment of the present disclosure;

FIG. 5 is a cross-sectional view of an electronic apparatus according to a third embodiment of the present disclosure;

FIG. 6 is a cross-sectional view of an electronic apparatus according to a fourth embodiment of the present disclosure;

FIG. 7 is a cross-sectional view of an electronic apparatus according to a fifth embodiment of the present disclosure;

FIG. 8 is a cross-sectional view of an electronic apparatus according to a sixth embodiment of the present disclosure;

FIG. 9 is a cross-sectional view of an electronic apparatus according to a modification of the present disclosure; and

FIG. 10 is a cross-sectional view of an electronic apparatus according to another modification of the present disclosure.

### EMBODIMENTS FOR CARRYING OUT INVENTION

Hereinafter, embodiments of the present disclosure will be described with reference to the drawings. In the following description, elements that are identical or equivalent to each other in the respective embodiments are denoted with the same reference signs.

### First Embodiment

A first embodiment of the present disclosure will be described with reference to the drawings. This electronic apparatus is mounted on a vehicle such as an automobile, and can be suitably applied as an apparatus for driving various devices for the vehicle.

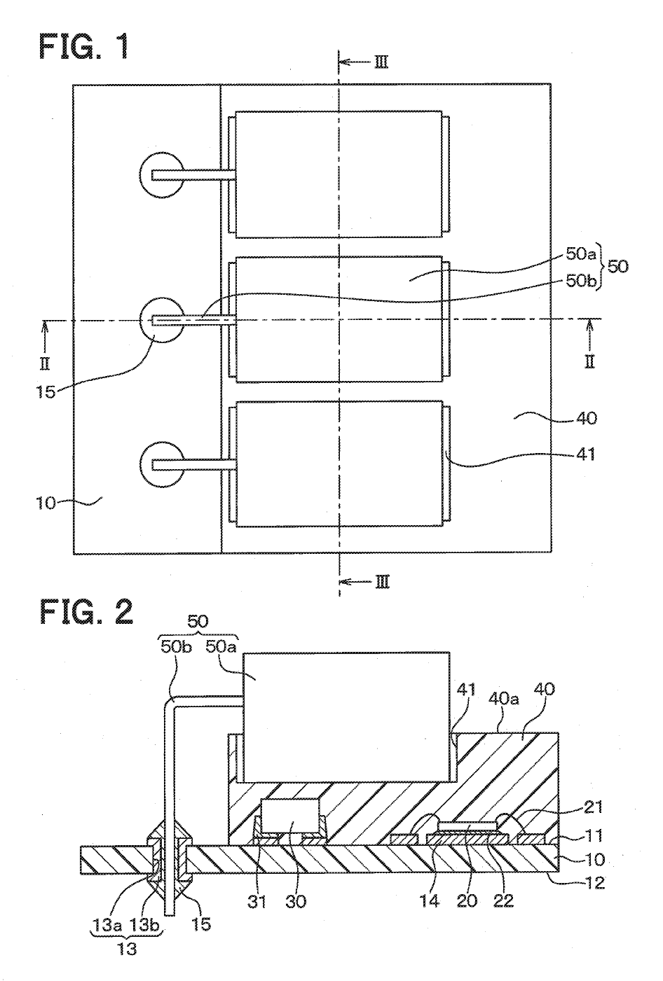

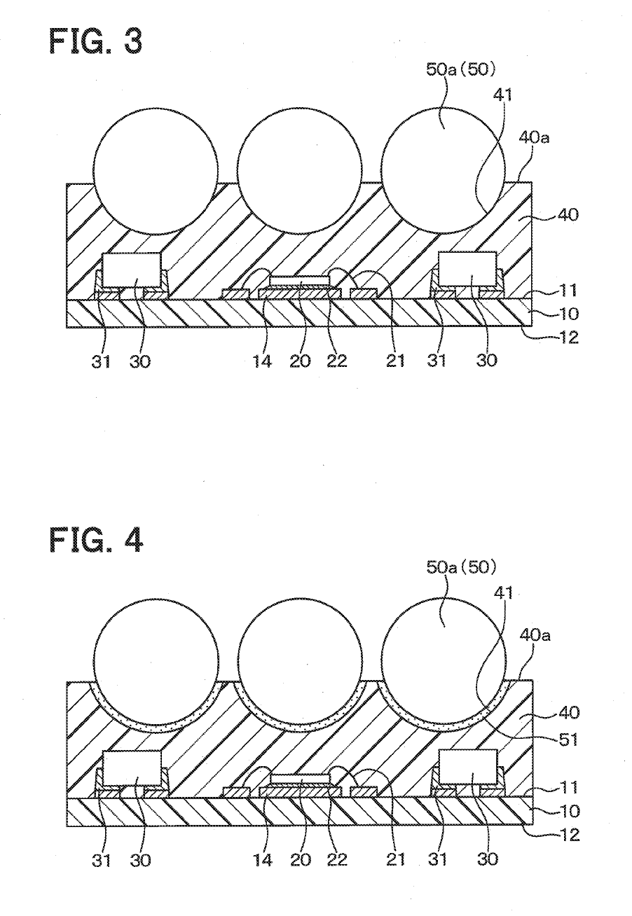

As shown in FIGS. 1 to 3, the electronic apparatus is configured to include a board 10, first electronic components 20 and 30, a mold resin 40, a second electronic component 50, and the like.

The board 10 is formed of a plate-like member having a first surface 11 on which the electronic components 20 and 30 are mounted and the mold resin 40 is disposed, and a second surface 12 opposite to the first surface 11. In this embodiment, the board 10 has a rectangular top plan shape. The board 10 in this embodiment is formed as a wiring board basically made of a resin such as an epoxy resin, and is configured as a through-hole board, a buildup board, or the like.

The board 10 has a wiring pattern (not shown) formed on the board and configured with an inner wiring layer, a surface wiring layer, or the like.

The wiring pattern (surface wiring pattern) is encapsulated in the mold resin 40 in conjunction with the first electronic components 20 and 30, and extends to the outside of the mold resin 40.

The board 10 also has through-hole electrodes 13 provided on portions exposed from the mold resin 40, and the through-hole electrodes 13 each include a through-hole 13a extending through between the first surface 11 and the second surface 12 and a metal film 13b formed on a wall surface of the through-hole 13a and electrically connected to the wiring pattern.

The first electronic components 20 and 30 are electrically connected to the wiring pattern by being mounted on the board 10, and may be surface-mounted components or the like. In this embodiment, the first electronic components 20 and 30 are described as a semiconductor element 20 and a passive element 30 as examples. Each of the semiconductor element 20 and the passive element 30 is not broken by the pressure exerted from the mold resin 40 during the molding.

Examples of the semiconductor element 20 include a microcomputer, a control element, and power elements such as an IGBT (Insulated Gate Bipolar Transistor) or a MOSFET (Metal-Oxide-Semiconductor Field-Effect Transistor). This semiconductor element 20 is connected to a land 14 on the board 10 with a bonding wire 21 and a die bonding material 22 such as solder.

Examples of the passive element 30 include a chip resistance, a chip capacitor, a quartz crystal oscillator, and the like. This passive element 30 is connected to a land 14 on the board 10 with a die bonding material 31 such as solder.

The lands 14 are either connected to the wiring pattern or configured with part of the wiring pattern. Therefore, the first electronic components 20 and 30 are electrically connected to the wiring pattern formed on the board 10, and are electrically connectable to external circuits via the through-hole electrodes 13 that are connected to the wiring pattern.

The mold resin 40 is configured with a thermosetting resin or the like such as an epoxy resin, and formed by a transfer molding or compression molding method with the use of a metal mold. In this embodiment, the first electronic components 20 and 30 and the first surface 11 of the board 10 are encapsulated in the mold resin 40, while the through-hole electrodes 13 and the second surface 12 of the board 10 are exposed, which is a so-called half-molded structure.

The mold resin 40 has a surface 40a parallel to the first surface 11 of the board 10 on a side opposite to the first surface 11, and the surface 40a has recesses 41 formed in the surface 40a and recessed toward the first surface 11 of the board 10. In this embodiment, the recesses 41 are formed at three locations on the surface 40a, and a wall surface of each recess 41 has a curved form that conforms to a contour of each second electronic component 50.

In this embodiment, the surface 40a of the mold resin 40 corresponds to a portion of the mold resin opposite to the board in the present disclosure. Each of the recesses 41 is provided by forming the mold resin 40 with the use of a mold having a protrusion corresponding to the recess 41 or by removing resin by laser processing or the like from the side of the surface 40a after forming the mold resin 40.

The number of second electronic components 50 in this embodiment is three, all the second electronic elements 50 are through-hole-mounted components, such as electric field capacitors, coils, diodes, transistors, shunt resistors, and jumper lines, which are likely broken by the pressure applied during the molding of the mold resin 40. Here, an electric field capacitor is shown as one example of the second electronic components 50, which includes a main body 50a having a columnar contour, and a connection terminal 50b at one end of the main body 50a in the longitudinal direction. The main bodies 50a are disposed so as to be positioned inside spaces defined in the recesses 41 in the mold resin 40 along the wall surfaces of the recesses 41. That is, the main bodies 50a are fitted into the recesses 41 and are in contact with the mold resin 40. The connection terminals 50b are inserted into the through-holes 13a and are electrically and mechanically connected to the metal films 13b via solder 15.

In this embodiment, the main bodies 50a are not secured to, but are in contact with the recesses 41, so that the second electronic components 50 are fixed in position by the connection terminals 50b mechanically connected to the metal films 13b via the solder 15. The main bodies 50a are placed in the recesses 41 so as to partly protrude from the surface 40a of the mold resin 40. Moreover, each of the connection terminals 50b is made of, for example, a tin- or nickel-plated copper alloy.

As described above, in this embodiment, the second electronic components 50 are disposed on the mold resin 40. Therefore, as compared to an electronic apparatus including second electronic components 50 disposed on a portion, which is not encapsulated in a mold resin 40, of a first surface 11 of a board 10, the board 10 can be made smaller.

The recesses 41 are formed in the surface 40a of the mold resin 40, and the main bodies 50a of the second electronic components 50 are positioned in the spaces defined in the recesses 41. Therefore, as compared to an electronic apparatus in which main bodies 50a of second electronic components 50 are simply disposed on a mold resin 40, the electronic apparatus can be made even smaller.

The recesses 41 are each recessed in a shape that conforms to the contour of the main body 50a, so that the main bodies 50a are set in position relative to the board 10 by being placed along the recesses 41. Therefore, variations in the mounting positions of the main bodies 50a can be reduced.

### Second Embodiment

A second embodiment of the present disclosure will be described. In this embodiment, as compared to the first embodiment, second electronic components 50 are secured to recesses 41. Description of other features is omitted here, since they are the same as those of the first embodiment.

As shown in FIG. 4, in this embodiment, the second electronic components 50 are secured to the recesses 41 via a joint member 51 such as an adhesive or a gel. That is, the second electronic components 50 (main bodies 50a) are disposed to be in contact with the mold resin 40 (recesses 41) via the joint member 51.

With this configuration, even if the electronic apparatus is used in an environment with large vibrations, stress concentration to the joints between the connection terminals 50b and solder 15 is restricted since the main bodies 50a are also secured to the recesses 41, so that the solder 15 can have longer life.

### Third Embodiment

A third embodiment of the present disclosure will be described. In this embodiment, as compared to the first embodiment, no recess 41 is formed in a mold resin 40. Description of other features is omitted here, since they are the same as those of the first embodiment.

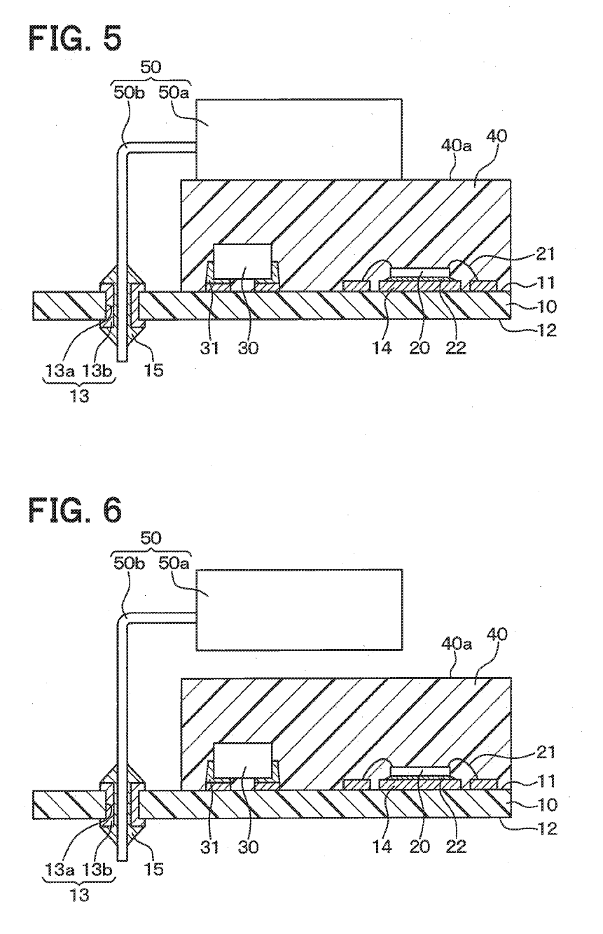

As shown in FIG. 5, in this embodiment, no recess 41 is formed in the mold resin 40. A second electronic component 50 (main body 50a) is disposed on a surface 40a of the mold resin 40 so as to be in contact with the mold resin 40. In this embodiment, a component having a parallelepiped main body 50a is used as the second electronic component 50.

Also in such an electronic apparatus, as compared to an electronic apparatus in which a second electronic component 50 is disposed on a portion, which is not encapsulated in a mold resin 40, of a first surface 11 of a board 10, the board 10 can be made smaller.

### Fourth Embodiment

A fourth embodiment of the present disclosure will be described. In this embodiment, as compared to the first embodiment, a second electronic component 50 is disposed to be spaced apart from a mold resin 40. Description of other features is omitted here, since they are the same as those of the first embodiment.

As shown in FIG. 6, in this embodiment, no recess 41 is formed in the mold resin 40. The second electronic component 50 is disposed above the mold resin 40 so as to be spaced apart from the mold resin 40. That is, the second electronic component 50 is disposed above the mold resin 40 so as not to be in contact with the mold resin 40.

With this configuration, stress resulting from a difference in thermal expansion coefficient between the second electronic component 50 and the mold resin 40 can be restricted, and a malfunction of the second electronic component 50 caused by such stress can be prevented.

### Fifth Embodiment

A fifth embodiment of the present disclosure will be described. This embodiment has a different second electronic component 50 from that of the first embodiment. Description of other features is omitted here, since they are the same as those of the first embodiment.

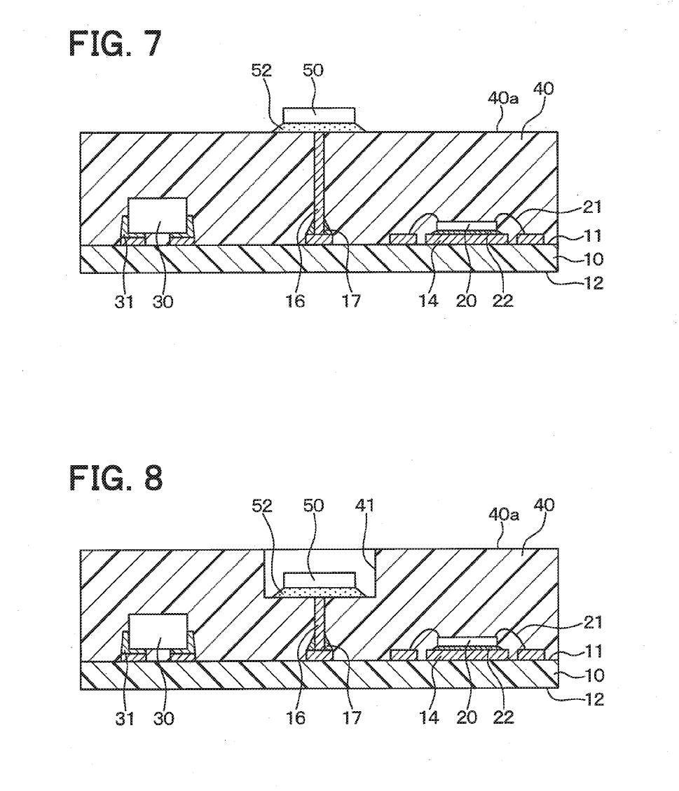

As shown in FIG. 7, in this embodiment, no recess 41 is formed in the mold resin 40. A rod-like electrode 16 is mounted on one of the lands 14 on the board 10 via a die bonding material 17. More specifically, the electrode 16 is parallel to a normal direction relative to the first surface 11 of the board 10, and is mounted such that part (distal end face) thereof is exposed from the surface 40a of the mold resin 40.

Moreover, in this embodiment, an IC element having a Hall element or the like that outputs a sensor signal in accordance with a magnetic field is used as the second electronic component 50, which has no connection terminal 50b. This second electronic component 50 is unlikely to be broken by the pressure applied during the molding of the mold resin 40.

The second electronic component 50 has an electrode or the like (not shown) and is secured to the mold resin 40 via a conductive adhesive 52 or the like so as to be electrically connected to the electrode 16 exposed from the mold resin 40.

As described above, even when the second electronic component 50 to be used does not have a connection terminal and is less likely to be broken by the pressure applied during the molding of the mold resin 40, the board 10 can be made smaller by disposing the second electronic component 50 on the mold resin 40.

### Sixth Embodiment

A sixth embodiment of the present disclosure will be described. In this embodiment, as compared to the fifth embodiment, a recess 41 is formed in a mold resin 40. Description of other features is omitted here, since they are the same as those of the first embodiment.

As shown in FIG. 8, in this embodiment, as with the first embodiment, the recess 41 that is recessed toward the first surface 11 of the board 10 is formed in the surface 40a of the mold resin 40. The electrode 16 is mounted such that part (distal end face) of the electrode 16 is exposed from the bottom surface of the recess 41.

The second electronic component 50 is secured to the bottom surface of the recess 41 via a conductive adhesive 52 or the like, and is electrically connected to the electrode 16 exposed from the bottom surface of the recess 41. The second electronic component 50 is accommodated in the recess 41 such that part thereof on the opposite side to the first surface 11 of the board 10 is positioned closer to the board 10 than the surface 40a of the mold resin 40. In other words, the second electronic component 50 is accommodated in the recess 41 so as not to partly protrude from the surface 40a of the mold resin 40.

With this configuration, as compared to a case where a second electronic component 50 is mounted on a surface 40a of a mold resin 40, the second electronic component 50 can be positioned closer to a detection target, so that the detection sensitivity can be enhanced.

Furthermore, in this embodiment, the second electronic component 50 is accommodated inside the recess 41 such that part thereof on the opposite side to the first surface 11 of the board 10 is positioned closer to the board 10 than the surface 40a of the mold resin 40. Therefore, even if a transfer jig or the like comes into contact with the surface 40a of the mold resin 40 during a transfer step or the like, the second electronic component 50 is prevented from coming into contact with the transfer jig, so that the second electronic component 50 is less likely to be damaged.

### Modifications

The present disclosure is not restricted to the above embodiments, and may be changed within the scope of claim.

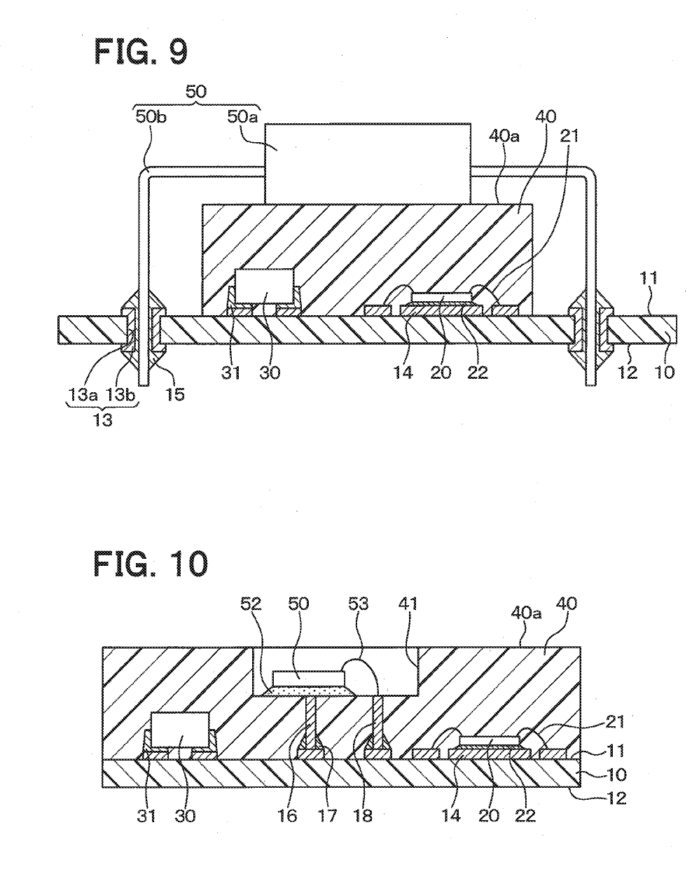

For example, in the third embodiment, a second electronic component 50 that has connection terminals 50b at both ends in the longitudinal direction of a main body 50a may be used, as shown in FIG. 9. Similarly, in the first, second, and fourth embodiments, although not particularly shown, a component that has connection terminals 50b at both ends in the longitudinal direction of a main body 50a may be used.

In the sixth embodiment, a second electronic component 50 that has an electrode or the like formed also on an opposite side to the bottom surface of the recess 41 may be used. In this case, as shown in FIG. 10, an additional electrode 18 may be provided with part (distal end face) thereof exposed from the bottom surface of the recess 41, and is electrically connected to the second electronic component 50 via a bonding wire 53. Also, a second electronic component 50 that has an electrode or the like formed only on an opposite side to the bottom surface of the recess 41 may be used. Similarly, also in the fifth embodiment, an electrode 18 may be provided, and the electrode 18 may be electrically connected to the second electronic component 50 via a bonding wire 53.

In the case of connecting the electrode 18 with the second electronic component 50 via a bonding wire 53, a pad connected to the electrode 18 may be formed on the bottom surface of the recess 41, and this pad may be electrically connected to the second electronic component 50 via the bonding wire 53.

In the sixth embodiment, the second electronic component 50 may be of such a size that it partly protrudes from the recess 41. The board 10 can still be made smaller in such an electronic apparatus.

The respective embodiments can be combined suitably. For example, the second embodiment may be combined with the third embodiment described above, such that the joint member 51 is disposed between the main body 50a and the surface 40a of the mold resin 40 and the main body 50a may be secured to the mold resin 40. In other words, the second electronic component 50 (main body 50a) may be brought into contact with the mold resin 40 via the joint member 51.

1. An electronic apparatus comprising:
a board having a first surface and a second surface opposite to the first surface;
a first electronic component mounted on the first surface of the board;
a mold resin sealing the first electronic component and the first surface of the board; and
a second electronic component arranged on the mold resin.

2. The electronic apparatus according to claim 1,
wherein the second electronic component is electrically connected to the board.

3. The electronic apparatus according to claim 2,
wherein the second electronic component is arranged to be spaced apart from the mold resin.

4. The electronic apparatus according to claim 2,
wherein the second electronic component is in contact with the mold resin.

5. The electronic apparatus according to claim 4, wherein:
the mold resin has a recess arranged in a portion on an opposite side to the board and recessed toward the first surface of the board; and
the second electronic component is arranged to be located in a space defined inside the recess.

6. The electronic apparatus according to claim 5, wherein:
the board includes a through-hole electrode arranged in a portion exposed from the mold resin, the through-hole electrode including a through-hole penetrating between the first surface and the second surface, and a metal film arranged in the through-hole; and
the second electronic component has a main body arranged in the recess, and a connection terminal arranged on the main body and connected to the through-hole electrode via solder.

7. The electronic apparatus according to claim 6, wherein:
the recess is recessed in a shape along an outline of the main body; and
the main body is positioned relative to the board by arranging the main body along the recess.

8. The electronic apparatus according to claim 7,
wherein the main body is fitted in the recess and is in contact with the recess.

9. The electronic apparatus according to claim 7,
wherein the main body is in contact with the mold resin by fixing the main body to the recess via a joint member.

10. The electronic apparatus according to claim 2, wherein:
the board includes an electrode sealed in the mold resin and partly exposed from the mold resin, and
the second electronic component is electrically connected to the electrode.

11. The electronic apparatus according to claim 10, wherein:
the mold resin has a recess arranged in a portion on an opposite side to the board and recessed toward the first surface of the board;
the electrode is partially exposed from the recess; and
the second electronic component is accommodated in the recess and is arranged such that a portion of the second electronic component on an opposite side to the first surface of the board is arranged closer to the board than a portion of the mold resin on an opposite side to the board.
